(19) United States
(12) Patent Application Publication
(10) Pub. No.: US 2009/0184714 A1
(43) Pub. Date: Jul. 23, 2009

(54) HOUSING FOR A MAGNETIC RESONANCE IMAGING SCANNER AND A SCANNER

(75) Inventors: Neil Charles Tigwell, Witney (GB); Stephen Paul Trowell, Finstock (GB)

Correspondence Address: CROWELL & MORING LLP;INTELLECTUAL PROPERTY GROUP, P.O. BOX 14300, WASHINGTON, DC, 20044-4300, US

(73) Assignee: Siemens Magnet Technology Ltd., Witney (GB)

(21) Appl. No.: 12/337,294

(22) Filed: Dec. 17, 2008

(30) Foreign Application Priority Data
Jan. 22, 2008 (GB) 0801116.5

(51) Int. Cl. G01R 33/3815

(52) U.S. Cl. 324/318

(57) ABSTRACT

Pumping out of a vacuum vessel and housing of a scanner is facilitated by providing a hole through a radiation shield. To reduce radiation of heat via this hole to an inner coolant containing vessel a closure member is provided. This is held in spaced apart relationship during pump down by clips. The closure member is provided with a ferrous constituent or member which is then attracted inwards during initialization of the superconducting. This draws the closure member into engagement with the shield to close the hole and to prevent radiation thereby. The clips are profiled to maintain the abutment of the closure member over the hole.

This invention relates to a Magnetic Resonance Imaging scanner and in particular to a housing for such a scanner which minimizes heating of helium held within the housing.

Magnetic Resonance Imaging (MRI) scanners typically utilize large superconducting magnets which require cooling to liquid helium temperatures for successful operation. A containment structure is provided to enclose the magnets and to hold a large volume of the liquid helium to provide the cooling. Liquid helium is very expensive and thus the structure is designed to minimize its loss through heating from the environment where the scanner is located. A multilayer structure is provided which is designed to prevent heat passing into the helium by conduction, convection and radiation.

The structure comprises a helium vessel which is innermost, a radiation shield spaced apart form the helium vessel, a number of layers of aluminized Mylar (registered trade mark—®) polyester sheets and insulation mesh, and then the outer vessel. This structure is evacuated during manufacture to minimize transfer from the outer vessel by convection.

To create the vacuum in the housing, it is necessary to provide a port for connection to a vacuum pump. The pumping down to the state required can take a few days due to the need for migration of the molecules through the port once low pressure are achieved. To assist in this in this process, it is desirable to provide a large port to increase the chances of trapped air molecules chancing upon the exit and a passageway through the Mylar® foil insulation and also the radiation shield.

Unfortunately, in prior art arrangements, once the vacuum is created and the port is closed by a cap there is a path for radiation from the cap which is relatively hot through the hole in the Mylar® aluminized polyester sheets and the heat shield to the helium vessel itself. This leads to undesirable heating of the helium vessel which leads to expensive helium loss.

According to the invention there is provided a housing for a superconducting magnet, which housing comprises an outer vacuum vessel housing a coolant vessel for, in use, holding a volume of coolant for cooling a superconducting magnet, a radiation shield for shielding the coolant vessel from radiated heat, a hole through the radiation shield adjacent a pump-out port and a closure member located over the hole and its periphery but adapted to be spaced apart therefrom during manufacture to permit passage of molecules therebetween during pumping out of the outer vacuum vessel, wherein the closure member comprises, at least in part, a ferrous material such that after the pumping out operation, energizing an associated superconducting magnet draws the closure member inwards to abut the periphery of the hole to close the hole to prevent radiation of heat therethrough.

Preferably, the closure member is spaced apart from the hole by a means which permits the relative inwards movement of the closure member but prevents outwards movement. The means may be a web of flexible material provided at locations about the periphery but in the preferred embodiment is a clip.

After energizing the magnet, the closure member abuts the periphery and it may be retained thereto by an adhesive. In the preferred embodiment it is retained by a clip. In this particular case the clip is the same that provided the spaced apart relationship. In its preferred form the clip is resiliently deformable and comprises a first location bounded by walls formed in the clip and a second location also formed by walls formed in the clip. The closure member is retained at the first location until the magnets are energized; this causes an inward attractive force which is sufficient to deflect the walls of the clip to allow passage of the clip into the second location. By virtue of the resilience of the clip, the walls revert back to their original shape to retain the panel at the second location.

The closure member may be a homogenous ferrous material, or may have a discrete ferrous part or parts. This latter option will be advantageous in order that the part which abuts the radiation shield may be formed from a compatible material to avoid material mismatch problems for example differential corrosion (the radiation shield is often made of high grade aluminum).

Preferably, the closure member is formed to have a reflective surface to minimize thermal radiation.

A specific embodiment of the invention will now be described, by way of example only, with reference to the accompanying drawings in which:

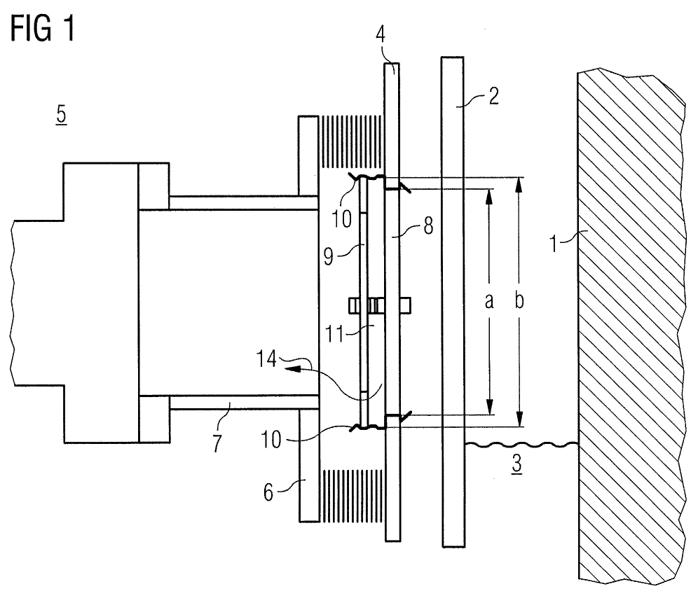

FIG. 1 shows a section through a closure arrangement of a housing for a Magnetic Resonance Imaging scanner in accordance with the invention during a pump down process;

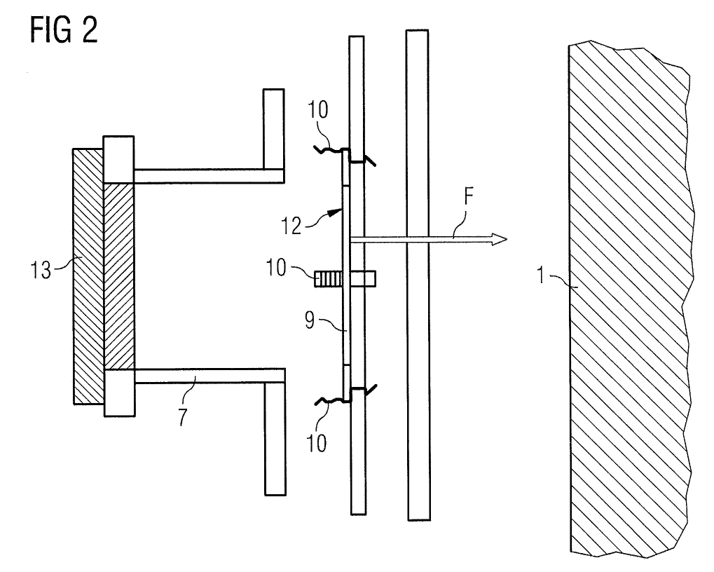

FIG. 2 shows the arrangement of FIG. 1 after pump down and closure of the housing; and

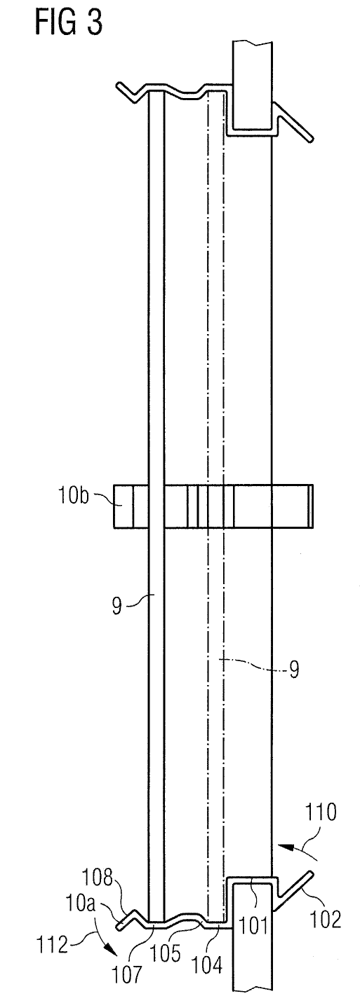

FIG. 3 shows in greater detail the closure member and associated retaining clips with the panel shown at the pre and post pump down locations.

As is shown in FIG. 1, a MRI scanner includes a set of superconducting coils 1 surrounded by a helium vessel 2 which, in use, contains liquid helium 3. A radiation shield 4 of high grade aluminum is provided about the helium vessel to prevent radiation of heat inwards to the helium vessel 2 from the outside environment 5. This is in spaced apart relationship to the helium vessel 2 to prevent heat transfer by conduction. The housing is completed by an outer vacuum vessel 6 again spaced away from the radiation shield to prevent heat transfer with the space therebetween which is itself filed with reflective Mylar® aluminized polyester sheets and insulating mesh.

The housing needs to be evacuated to prevent heat transfer and is provided with a cylindrical pump out port 7. The outer end is provided with a flange to permit the attachment of a pump (not shown). To improve the pump down process a circular hole 8 of diameter a is formed in the radiation shield 4.

A closure member 9 is provided which is in the form of a disc having a diameter b which is greater than a such that the closure member 9 overlaps the periphery of the hole 8. Four clips 10 are provided (three of which are shown) engaging the periphery and the closure member 9 to hold the closure member in position in a spaced apart and centered relationship to the hole 8. This provides a generally cylindrical clearance gap 11 which facilitates air removal during pump down as shown by the flow path indicated by arrow 14.

FIG. 2 shows the arrangement after pump down and after initial ramping up of the magnets 1. Ramping up of the magnets 1 provides an inwards attractive force F on the closure member 9. The closure member 9 has a ferrous component and is drawn inwards. This is permitted by a deformation of the clips 10 (to be described later) until the closure member abuts to the radiation shield. It is retained in abutting contact when the magnets are switched off by the clips 10. The outer surface 12 of the closure member 9 is made to be highly reflective to enhance its radiation shielding qualities. This prevents heating of the helium vessel by radiation of heat from the pump out port 7. A seal 13 is placed over the port after the pump-out process is completed. These components will be at the outside environmental temperature.

The clips 10 and the closure member 9 are shown in greater detail in FIG. 3. In the figure, the first pre-pump-down position is shown in solid outline and the final pumped-down and closed position is shown in broken outline. The clips 10 are nominally identical and formed of a plastics material such as glass reinforced nylon. They have a generally ribbon like appearance when viewed in plan, as may be most easily seen in clip 10b. The shape when viewed sideways on is more complex as will be apparent from the depiction of clip 10a. It includes a periphery gripping rebate 101 which is channel-like and defined by three walls. To facilitate the opening of this rebate to place the clip over the wall of the hole 8, a biasing arm 102 is provided to allow an installer to apply an opening pressure in the direction of labeled arrow 110. Progressing outwards along the clip 10a, it will be seen that a retaining location is provided by a flange which closely conforms to the generally planar profile of the outer surface of the periphery of the hole 8, an end wall 104 and a shallow retaining wall 105. It will be seen that the retaining wall 105 extends inwards to engage the outermost face of the closure member shown in broken outline to retain it in this closed position. The retaining wall 105 curves gently outwards to provide a second shallow walled rebate 107 which holds the closure member in the first initial pre-pump down location. To facilitate the initial positioning of the closure member into this location, the shallow rebate can be opened using the spring-arm 108 and applying a pressure to it in the direction of labeled arrow 112.

An important feature of the clip 10 is the shallow curving nature of the retaining wall 105 which assists in the smooth inward movement of the closure member 9 and the sharper profile after the peak of the curve to provide a secure retention in the closed position.

It will be appreciated that the precise profile of the clip may be varied and materials other than plastics may be used such as a metal. While the invention has been described with particular reference to MRI scanners, it will be appreciated that the invention may be applied to housings for any superconducting magnets. Similarly, while the description makes particular reference to helium coolant, the invention is applicable to magnets cooled by any suitable cryogen, such as nitrogen, hydrogen, neon and so on.

1. A housing for a superconducting magnet, which housing comprises an outer vacuum vessel housing a coolant vessel for, in use, holding a volume of coolant for cooling a superconducting magnet, a radiation shield for shielding the coolant vessel from radiated heat, a hole through the radiation shield adjacent a pump-out port and a closure member located over the hole and its periphery but adapted to be spaced apart therefrom during manufacture to permit passage of molecules therebetween during pumping out of the outer vacuum vessel, wherein the closure member comprises, at least in part, a ferrous material such that after the pumping out operation, energizing an associated superconducting magnet draws the closure member inwards to abut the periphery of the hole to close the hole to prevent radiation of heat therethrough.

2. A housing as claimed in claim 1 wherein the closure member is held to the heat shield by a clip.

3. A housing as claimed in claim 2 wherein the clip maintains the spaced apart relationship.

4. A housing as claimed in claim 2 wherein the clip maintains the abutment of the closure member to the radiation shield.

5. A housing as claimed in claim 4 wherein the clip is resiliently deformable to permit the drawing of the closure member into abutment.

6. A housing as claimed in claim 5 wherein the clip engages a wall of the periphery of the hole.

7. A housing as claimed in claim 6 wherein the clip is retained in engagement by a spring bias provided by the clip.

8. A housing as claimed in claim 1 when dependent on claim 2 wherein the clip provides a second location region, wherein the closure member is held in abutment, separated from a first location, wherein the closure member is in spaced apart relationship, by a lip having a profile to enable ramping of the closure member over the lip and into the second location.

9. A housing as claimed in claim 8 wherein the lip has a profile which prevents movement out of the second location.

10. A housing as claimed in claim 1 wherein the closure member is provided, at least over an abutting part, with a material compatible with the material of the radiation shield.

11. A MRI scanner comprising a housing as claimed in claim 1.

12. A housing as claimed in claim 3 wherein the clip maintains the abutment of the closure member to the radiation shield.
